(19) United States
(12) Patent Application Publication
(10) Pub. No.: US 2013/0075847 A1
(43) Pub. Date: Mar. 28, 2013

(54) MAGNETIC MEMORY

(71) Applicant: Hiroaki Honjou, Tokyo (JP)

(72) Inventor: Hiroaki Honjou, Tokyo (JP)

(73) Assignee: NEC CORPORATION, TOKYO (JP)

(21) Appl. No.: 13/636,318

(22) PCT Filed: Mar. 16, 2011
(86) PCT No.: PCT/JP2011/056158

§ 371 Date: Nov. 30, 2012

(30) Foreign Application Priority Data
Mar. 23, 2010 (JP) 2010-066930

(51) Int. Cl. H01L 29/82

(52) U.S. Cl. CPC H01L 29/82
USPC 257/421

(57) ABSTRACT

A magnetic memory has: a pinning layer being a perpendicular magnetic film whose magnetization direction is fixed; an underlayer formed on the pinning layer; and a data storage layer being a perpendicular magnetic film formed on the underlayer. The data storage layer has: a magnetization free region whose magnetization direction is reversible; and a magnetization fixed region magnetically coupled with the pinning layer through the underlayer. A magnetization direction of the magnetization fixed region is fixed by the magnetic coupling. The underlayer has a magnetic underlayer made of a magnetic material.

### TECHNICAL FIELD

The present invention relates to a magnetic memory. In particular, the present invention relates to a magnetic memory that utilizes current driven domain wall motion and is provided with a data storage layer having perpendicular magnetic anisotropy.

### BACKGROUND ART

A magnetic memory, particularly a magnetic random access memory (Magnetic Random Access Memory; MRAM) is a nonvolatile memory capable of a high speed operation and an infinite number of rewritings. Therefore, some MRAMs are put into practical use, and development is carried out for further improving versatility. The MRAM uses a magnetic material as a memory element and stores a data with associating it with a magnetization direction of the magnetic material. In order to write a desired data to the memory element, the magnetization of the magnetic material is switched to a direction associated with the data. Although several methods have been proposed as a method of switching the magnetization direction, all of them are common with regard to the used of a current (hereinafter referred to as a “write current”). In putting the MRAM into the practical use, how much the write current can be reduced is very important.

According to Non Patent Literature 1 (N. Sakimura et al., MRAM Cell Technology for Over 500-MHz SoC, IEEE JOURNAL OF SOLID-STATE CIRCUITS, VOL. 42, NO. 4, pp. 830-838, 2007.), an equivalent cell area to that of an existing embedded SRAM can be achieved by reducing the write current to 0.5 mA or less.

The most typical one of data write methods to the MRAM is to dispose an interconnection for the writing in the vicinity of the magnetic memory element, to generate a magnetic field by flowing the write current through the interconnection, and to switch the magnetization direction of the magnetic memory element by using the magnetic field. This method is preferable in attaining the high speed MRAM, because the data write in one nanosecond or less can be achieved in principle. However, a magnetic field necessary for switching the magnetization of magnetic material which has sufficient thermal stability and resistance against external magnetic field disturbance is typically several ten Oe (oersteds), and a large write current around several mA is required to generate such a large magnetic field. In this case, the chip area is inevitably increased and power consumption required for the writing also is increased, which causes poor competitiveness as compared with other random access memories. In addition, the write current is further increased as the element is miniaturized, which is undesirable from a viewpoint of scaling property.

In recent years, the following two approaches have been proposed for solving such problems.

The first approach is a spin torque transfer method. According to the spin torque transfer method, a laminated film comprises a first magnetic layer having a reversible magnetization and a second magnetic layer electrically connected to it and whose magnetization direction is fixed, and a write current is supplied between the second magnetic layer and the first magnetic layer in the laminated film. At this time, the magnetization of the first magnetic layer can be reversed by an interaction between spin-polarized conduction electrons and localized electrons in the first magnetic layer. At a time of data read, a magnetoresistive effect occurring between the first magnetic layer and the second magnetic layer is utilized. Therefore, the magnetic memory element using the spin torque transfer is a two-terminal element. Since the spin torque transfer is caused when a current density is higher than a certain value, the current required for the data write is reduced as an element size becomes smaller. That is, the spin torque transfer method can be said to be superior in the scaling property. However, in general, an insulating layer is provided between the first magnetic layer and the second magnetic layer, and thus a comparatively large write current needs to flow penetrating through the insulating layer at the time of data write. This causes a problem of rewriting durability and reliability. Moreover, a write current path and a read current path are the same, and this may cause an erroneous data write in the data read. As thus described, there are several obstacles in attaining the practical use of the spin torque transfer, although the spin torque transfer is superior in the scaling property.

The second approach is a current driven domain wall motion method. The MRAM which utilizes the current driven domain wall motion is disclosed, for example, in Patent Literature 1 (Japanese Patent Publication JP-2005-191032). In a typical current driven domain wall motion MRAM, a magnetic layer (data storage layer) having a reversible magnetization is provided, and respective magnetizations of both end sections of the data storage layer are so fixed as to be anti-parallel to each other. Due to this magnetization configuration, a domain wall is introduced within the data storage layer. When a current is supplied in a direction that passes through the domain wall, the domain wall is moved in the direction of conduction electrons, as reported in Non Patent Literature 2 (A. Yamaguchi et al., Real-Space Observation of Current-Driven Domain Wall Motion in Submicron Magnetic Wires, PHYSICAL REVIEW LETTERS, VOL. 92, NO. 7, 077205, 2004). Therefore, by supplying a write current in an in-plane direction in the data storage layer, it is possible to move the domain wall in a direction depending on the current direction and thus to write a desired data. At a time of data read, a magnetic tunnel junction including a region in which the domain wall moves is used and the data read is performed based on the magnetoresistive effect. Therefore, the magnetic memory element using the current driven domain wall motion is a three-terminal element. Moreover, the current driven domain wall motion also is caused when a current density is higher than a certain value, as in the case of the spin torque transfer. Therefore, the current driven domain wall motion method also can be said to be superior in the scaling property. In addition to that, in the case of the current driven domain wall motion method, the write current does not flow through an insulating layer, and a write current path and a read current path are separated from each other. Therefore, the above-mentioned problems in the case of the spin torque transfer can be solved.

It should be noted that according to the above-mentioned Non Patent Literature 2, it is reported that the current density required for the current driven domain wall motion is about 1×10⁸ [A/cm2].

Non Patent Literature 3 (S. Fukami et al., Micromagnetic analysis of current driven domain wall motion in nanostrips with perpendicular magnetic anisotropy, JOURNAL OF APPLIED PHYSICS, VOL. 103, 07E718, 2008.) describes effectiveness of perpendicular magnetic anisotropy material with respect to the current driven domain wall motion method. More specifically, it has been revealed through a micromagnetic simulation that the write current can be reduced sufficiently in a case where the data storage layer in which the domain wall motion occurs has the perpendicular magnetic anisotropy.

Patent Literature 2 (Japanese Patent Publication JP-2008-135503) discloses a top pin type magnetoresistive element. The magnetoresistive element has an underlayer, a magnetization free layer formed on the underlayer and a magnetization fixed layer formed on the magnetization free layer through a nonmagnetic layer 34. The underlayer is made of a crystalline metal material. The crystal of the underlayer has several crystalline orientation components. Two ore more of the several crystalline orientation components are in contact with the magnetization free layer.

Patent Literature 3 (Japanese Patent Publication JP-2009-54715) discloses an MRAM that has a magnetization recording layer being a ferromagnetic layer having magnetic anisotropy and a read layer provided on the magnetization recording layer and used for reading out information. The magnetization recording layer has a magnetization switching region including a first magnetization switching region and a second magnetization switching region each having reversible magnetization, a first magnetization fixed region connected to a boundary with the first magnetization switching region and whose magnetization direction is fixed, and a second magnetization fixed region connected to a boundary with the second magnetization switching region and whose magnetization direction is fixed.

### CITATION LIST

### Patent Literature

[Patent Literature 1] Japanese Patent Publication JP-2005-191032
[Patent Literature 2] Japanese Patent Publication JP-2008-135503
[Patent Literature 3] Japanese Patent Publication JP-2009-54715

### Non Patent Literature

[Non Patent Literature 1] N. Sakimura et al., MRAM Cell Technology for Over 500-MHz SoC, IEEE JOURNAL OF SOLID-STATE CIRCUITS, VOL. 42, NO. 4, pp. 830-838, (2007).
[Non Patent Literature 2] A. Yamaguchi et al., Real-Space Observation of Current-Driven Domain Wall Motion in Submicron Magnetic Wires, PHYSICAL REVIEW LETTERS, VOL. 92, NO. 7, 077205, (2004).
[Non Patent Literature 3] S. Fukami et al., Micromagnetic analysis of current driven domain wall motion in nanostrips with perpendicular magnetic anisotropy, JOURNAL OF APPLIED PHYSICS, VOL. 103, 07E718, (2008).
[Non Patent Literature 4] A. Thiaville et al., Domain wall motion by spin-polarized current: a micromagnetic study, JOURNAL OF APPLIED PHYSICS, VOL. 95, NO. 11, pp. 7049-7051, (2004).
[Non Patent Literature 5] S. Fukami et al., Low-Current Perpendicular Domain Wall Motion Cell for Scalable High-Speed MRAM, Symposium on VLSI Technology, 12A-2, (2008).
[Non Patent Literature 6] G. H. O. Daalderop et al., Prediction and Confirmation of Perpendicular Magnetic Anisotropy in Co/Ni Multilayers, PHYSICAL REVIEW LETTERS, VOL. 68, NO. 5, pp. 682-685, (1992).
[Non Patent Literature 7] F. J. A. den Broeder et al., Perpendicular Magnetic Anisotropy and Coercivity of Co/Ni Multilayers, IEEE TRANSACTIONS ON MAGNETICS, VOL. 28, NO. 5, pp. 2760-2765, (1992).

### SUMMARY OF INVENTION

As described above, it has been revealed through the micromagnetic simulation that the write current can be reduced sufficiently small in the case where the data storage layer in which the domain wall motion occurs has the perpendicular magnetic anisotropy. Therefore, to form a ferromagnetic material having the perpendicular magnetic anisotropy as the data storage layer is expected to be preferable for reducing the write current in the magnetic memory utilizing the current driven domain wall motion.

Here, the inventors of the present patent application have recognized the following points. In order to actually manufacture a current driven domain wall motion type magnetic memory and to further reduce the write current, it is necessary to appropriately adjust a material of the data storage layer in which the domain wall motion occurs. More specifically, it is desirable to use a material having small saturation magnetization and large spin polarizability. Furthermore, the perpendicular magnetization must be achieved by using such the material. In other words, it is necessary to achieve crystal orientation such that the perpendicular magnetization can be obtained in the data storage layer.

Furthermore, in order to normally maintain the domain wall in the data storage layer, it is necessary to sufficiently fix a magnetization direction of a magnetization fixed region in the data storage layer. If the magnetization fixation of the magnetization fixed region is insufficient, the domain wall may get out of the data storage layer due to a data write operation, which may preclude a normal operation of the memory.

An object of the present invention is to provide a technique that can properly achieve a data storage layer having the perpendicular magnetic anisotropy and improve operation reliability, with regard to a magnetic memory that utilizes the current driven domain wall motion.

In an aspect of the present invention, a magnetic memory is provided. The magnetic memory has: a pinning layer being a perpendicular magnetic film whose magnetization direction is fixed; an underlayer formed on the pinning layer; and a data storage layer being a perpendicular magnetic film formed on the underlayer. The data storage layer has: a magnetization free region whose magnetization direction is reversible; and a magnetization fixed region magnetically coupled with the pinning layer through the underlayer. A magnetization direction of the magnetization fixed region is fixed by the magnetic coupling. The underlayer has a magnetic underlayer made of a magnetic material.

According to the present invention, it is possible to properly achieve a data storage layer having the perpendicular magnetic anisotropy and improve operation reliability, with regard to a magnetic memory that utilizes the current driven domain wall motion.

### BRIEF DESCRIPTION OF DRAWINGS

The above and other objects, advantages and features of the present invention will be more apparent from the following description of certain exemplary embodiments taken in conjunction with the accompanying drawings.

FIG. 1A is a side view showing a configuration of a magnetic memory element according to an exemplary embodiment of the present invention.

FIG. 1B is a plan view of the magnetic memory element shown in FIG. 1A.

FIG. 2A shows the “0” state of the magnetic memory element.

FIG. 2B shows the “1” state of the magnetic memory element.

FIG. 3A is a conceptual diagram showing a method of data write to the magnetic memory element.

FIG. 3B is a conceptual diagram showing a method of data write to the magnetic memory element.

FIG. 4A is a conceptual diagram showing a method of data read from the magnetic memory element.

FIG. 4B is a conceptual diagram showing a method of data read from the magnetic memory element.

FIG. 5 is a circuit diagram showing a configuration of one magnetic memory cell.

FIG. 6 is a graph showing a result of a measurement of underlayer film thickness dependence of a magnetization curve.

FIG. 7 is a graph showing a result of a measurement of underlayer film thickness dependence of a magnetization curve.

FIG. 8 is a side view showing a modification example of the magnetic memory element.

### DESCRIPTION OF EXEMPLARY EMBODIMENTS

A current driven domain wall motion type magnetic memory according to an exemplary embodiment of the present invention will be described with reference to the attached drawings.

### 1. Basic Structure and Principle

### 1-1. Basic Structure of Magnetic Memory Element

A magnetic memory according to the present exemplary embodiment has a plurality of magnetic memory cells that are arranged in an array form, and each magnetic memory cell has a magnetic memory element. A current driven domain wall motion type magnetic memory element has a data storage layer that stores a data depending on its magnetization state, a read structure for reading out the data stored in the data storage layer, and a current introduction structure for introducing a current to the data storage layer.

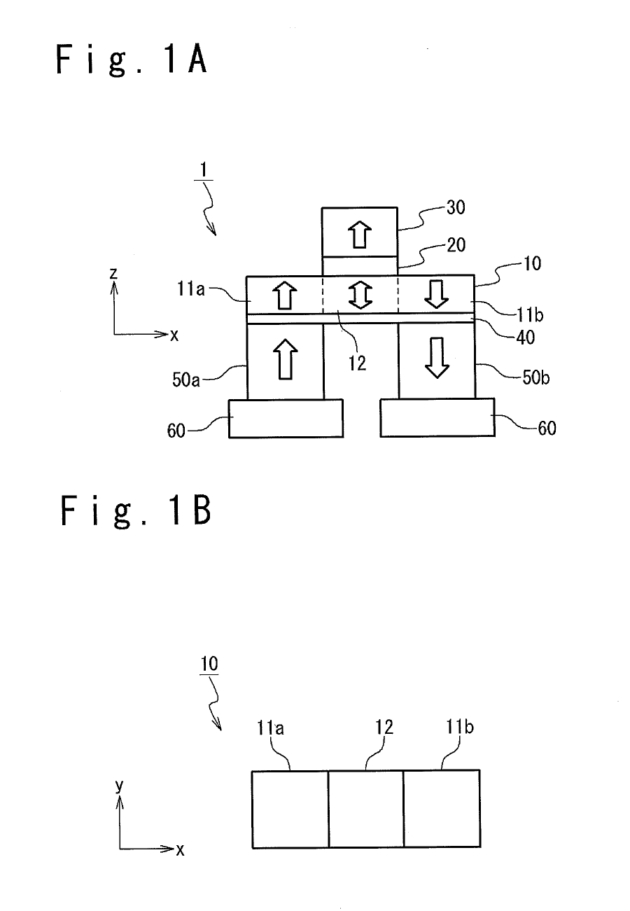

FIGS. 1A and 1B show a structural example of a magnetic memory element 1 according to the present exemplary embodiment. FIG. 1A is a side view and FIG. 1B is a plan view. In the x-y-z coordinate system described in the figures, the z-axis represents a direction perpendicular to a substrate, and the x-axis and the y-axis are parallel to the substrate plane. As shown in FIGS. 1A and 1B, the magnetic memory element 1 has a magnetization free layer 10, a nonmagnetic layer 20, a pinned layer 30, an underlayer 40, a pinning layer 50 and an electrode layer 60.

The magnetization free layer 10 is the above-mentioned “data storage layer” and is made of a ferromagnetic material. In particular, according to the present exemplary embodiment, the magnetization free layer 10 is formed of a perpendicular magnetic film having the perpendicular magnetic anisotropy. Also, the magnetization free layer 10 includes a region whose magnetization direction is reversible and stores a data depending on its magnetization state. More specifically, the magnetization free layer 10 has a first magnetization fixed region 11a, a second magnetization fixed region 11b and a magnetization free region 12. The magnetization fixed regions 11a and 11b are located on both sides of the magnetization free region 12, and the magnetization free region 12 is sandwiched between the magnetization fixed regions 11a and 11b. Respective magnetizations of the magnetization fixed regions 11a and 11b are fixed in the opposite directions. That is, the respective magnetization directions of the magnetization fixed regions 11a and 11b are anti-parallel to each other. For example, as shown in FIG. 1A, the magnetization direction of the first magnetization fixed region 11a is fixed in the +z-direction, and the magnetization direction of the second magnetization fixed region 11b is fixed in the −z-direction. On the other hand, the magnetization direction of the magnetization free region 12 is reversible and can be either the +z-direction or the −z-direction. Therefore, a domain wall is formed within the magnetization free layer 10, depending on the magnetization direction of the magnetization free region 12.

The nonmagnetic layer 20 is so provided as to be adjacent to the magnetization free layer 10. In particular, the nonmagnetic layer 20 is so provided as to be adjacent to at least the magnetization free region 12 of the magnetization free layer 10. The nonmagnetic layer 20 is made of a nonmagnetic material, preferably an insulating material.

The pinned layer 30 is so provided as to be adjacent to the nonmagnetic layer 20 on the opposite side of the magnetization free layer 10. That is, the pinned layer 30 is connected to the magnetization free layer 10 (magnetization free region 12) through the nonmagnetic layer 20. The pinned layer 30 is made of a ferromagnetic material and its magnetization direction is fixed in one direction. Preferably, the pinned layer 30 also is formed of a perpendicular magnetic film having the perpendicular magnetic anisotropy, as in the case of the magnetization free layer 10. In this case, the magnetization direction of the pinned layer 30 is fixed in either the +z-direction or the −z-direction. For example, in FIG. 1A, the magnetization direction of the pinned layer 30 is fixed in the +z-direction.

The above-described magnetization free layer 10 (magnetization free region 12), nonmagnetic layer 20 and pinned layer 30 form a magnetic tunnel junction (Magnetic Tunnel Junction; MTJ). Moreover, the nonmagnetic layer 20 and the pinned layer 30 correspond to the “read structure” for reading out the data stored in the magnetization free layer 10 being the data storage layer, as will be described later.

The underlayer 40 is provided on the substrate side of the magnetization free layer 10. As will be described later in detail, the magnetization free layer 10 having the perpendicular magnetic anisotropy is formed on the underlayer 40 by using the underlayer 40 as a base layer. That is, the magnetization free layer 10 is formed on the underlayer 40 so as to be in contact with the underlayer 40. The underlayer 40 is formed on the pinning layer 50.

The pinning layer 50 is provided on the substrate side of the underlayer 40. The pinning layer 50 is a perpendicular magnetic film whose magnetization direction is fixed and plays a role of fixing the magnetization directions of the magnetization fixed regions 11a and 11b of the magnetization free layer 10. More specifically, the pinning layer 50 has a first pinning layer 50a provided on a side of the first magnetization fixed region 11a and a second pinning layer 50b provided on a side of the second magnetization fixed region 11b. The first pinning layer 50a is magnetically coupled with the first magnetization fixed region 11a through the underlayer 40 and fixes the magnetization direction of the first magnetization fixed region 11a by the magnetic coupling. The second pinning layer 50b is magnetically coupled with the second magnetization fixed region 11b through the underlayer 40 and fixes the magnetization direction of the second magnetization fixed region 11b by the magnetic coupling. Respective magnetization directions of the first pinning layer 50a and the second pinning layer 50b are opposite to each other.

Two electrode layers 60 are provided so as to be connected respectively to the first pinning layer 50a and the second pinning layer 50b. The electrode layers 60 correspond to the above-mentioned “current introduction structure” and are used for introducing a current to the magnetization free layer 10 being the data storage layer.

### 1-2. Magnetization State of Magnetic Memory Element

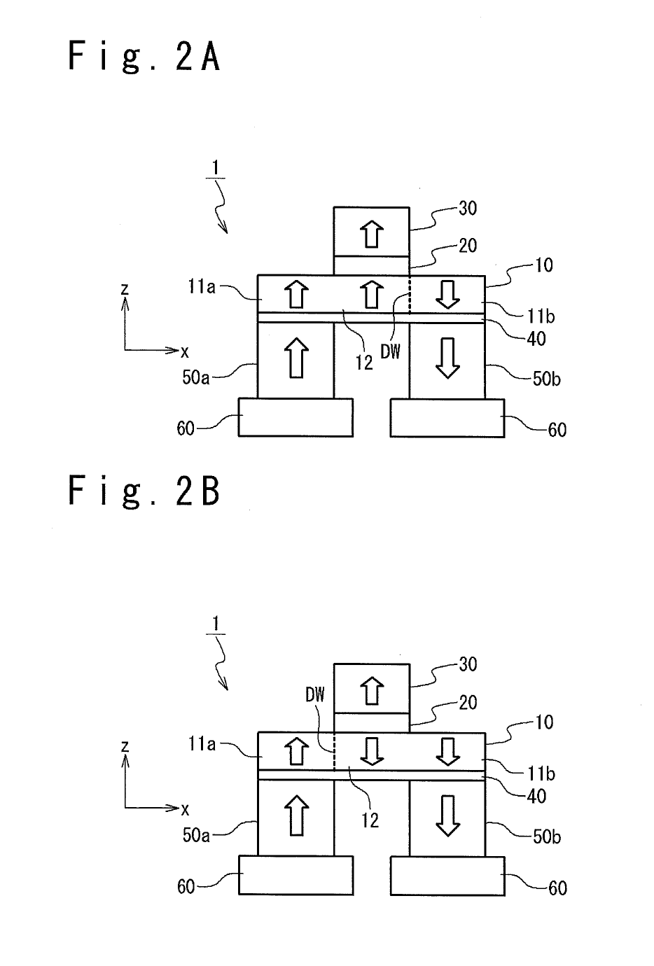

FIGS. 2A and 2B show two magnetization states that the magnetic memory element 1 shown in FIG. 1A can take. Here, let us consider a case where the magnetization directions of the magnetization fixed regions 11a and 11b of the magnetization free layer 10 are respectively fixed in the +z-direction and the −z-direction, and the magnetization direction of the pinned layer 30 is fixed in the +z-direction.

In FIG. 2A, the magnetization direction of the magnetization free region 12 of the magnetization free layer 10 is the +z-direction. In this case, a domain wall DW is formed at a boundary between the magnetization free region 12 and the second magnetization free region 11b. Also, the magnetization direction of the magnetization free region 12 and the magnetization direction of the pinned layer 30 are parallel to each other. Therefore, an MTJ resistance value becomes relatively small. Such a magnetization state is related to, for example, a data “0” magnetization state.

On the other hand, in FIG. 2B, the magnetization direction of the magnetization free region 12 of the magnetization free layer 10 is the −z-direction. In this case, the domain wall DW is formed at a boundary between the magnetization free region 12 and the first magnetization free region 11a. Also, the magnetization direction of the magnetization free region 12 and the magnetization direction of the pinned layer 30 are anti-parallel to each other. Therefore, the MTJ resistance value becomes relatively large. Such a magnetization state is related to, for example, a data “1” magnetization state.

In this manner, the two magnetization states can be achieved depending on the magnetization state of the magnetization free layer 10, namely, the position of the domain wall in the magnetization free layer 10. It should be noted that a correspondence relationship between the magnetization states defined in FIGS. 2A and 2B and the two magnetization states is arbitrary.

### 1-3. Data Write/Read Method

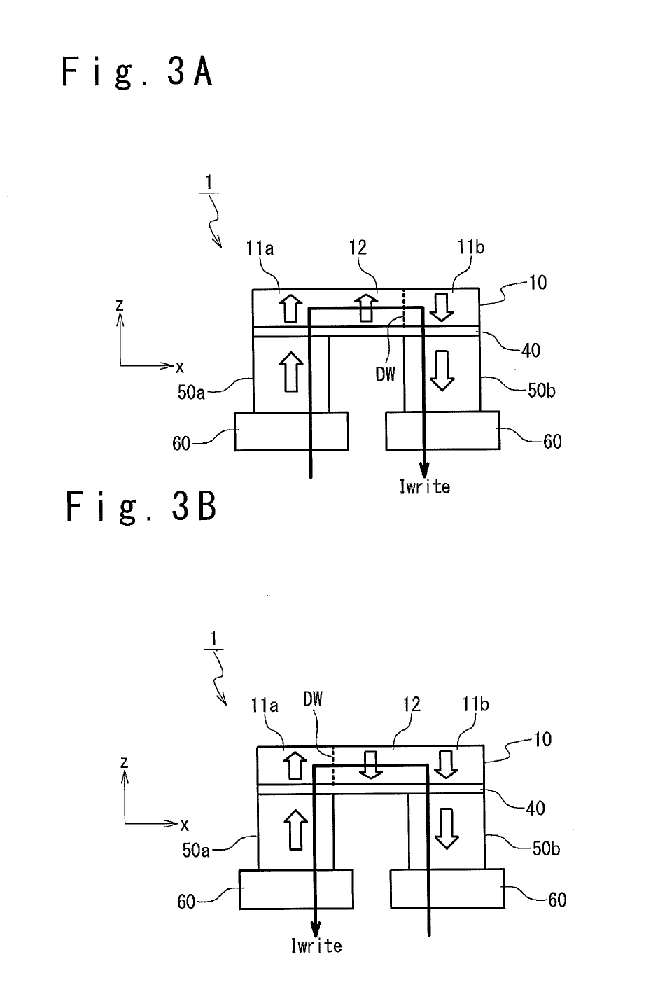

Next, a method of data write to the magnetic memory element 1 will be described with reference to FIGS. 3A and 3B. For simplicity, the nonmagnetic layer 20 and the pinned layer 30 are omitted in FIGS. 3A and 3B. According to the present exemplary embodiment, the data write to the magnetic memory element 1 is performed by the current driven domain wall motion method. For this purpose, the above-described electrode layers 60 (current introduction structure) connected to the magnetization free layer 10 having the domain wall DW are used. By using the two electrode layers 60, it is possible to supply the write current in an in-plane direction in the magnetization free layer 10 and thus to move the domain wall DW in a direction depending on the current direction. That is, the magnetization state of the magnetization free layer 10 can be switched between the two magnetization states shown in FIGS. 2A and 2B, by the current driven domain wall motion.

FIG. 3A shows a write current Iwrite in a case of the state switching from FIG. 2A (“0” state) to FIG. 2B (“1” state). As shown in FIG. 3A, the write current Iwrite is supplied from the first magnetization fixed region 11a through the magnetization free region 12 to the second magnetization fixed region 11b in the magnetization free layer 10. Therefore, conduction electrons flow from the second magnetization fixed region 11b through the magnetization free region 12 to the first magnetization fixed region 11a. At this time, the spin transfer torque (Spin Transfer Torque; STT) acts on the domain wall DW that is located in the vicinity of the boundary between the second magnetization fixed region 11b and the magnetization free region 12, and thereby the domain wall DW moves towards the first magnetization fixed region 11a. That is to say, the current driven domain wall motion is caused. The motion of the domain wall DW stops at in the vicinity of the boundary between the first magnetization fixed region 11a and the magnetization free region 12. In this manner, the magnetization state shown in FIG. 2B, namely, the data “1” write can be achieved.

FIG. 3B shows a write current Iwrite in a case of the state switching from FIG. 2B (“1” state) to FIG. 2A (“0” state). As shown in FIG. 3B, the write current Iwrite is supplied from the second magnetization fixed region 11b through the magnetization free region 12 to the first magnetization fixed region 11a in the magnetization free layer 10. Therefore, conduction electrons flow from the first magnetization fixed region 11a through the magnetization free region 12 to the second magnetization fixed region 11b. At this time, the spin transfer torque acts on the domain wall DW that is located in the vicinity of the boundary between the first magnetization fixed region 11a and the magnetization free region 12, and thereby the domain wall DW moves towards the second magnetization fixed region 11b. That is to say, the current driven domain wall motion is caused. The motion of the domain wall DW stops at in the vicinity of the boundary between the second magnetization fixed region 11b and the magnetization free region 12. In this manner, the magnetization state shown in FIG. 2A, namely, the data “0” write can be achieved.

It should be noted that no state transition occurs when the data “0” write is performed with respect to the data “0” state or the data “1” write is performed with respect to the data “1” state. That is, overwrite is possible.

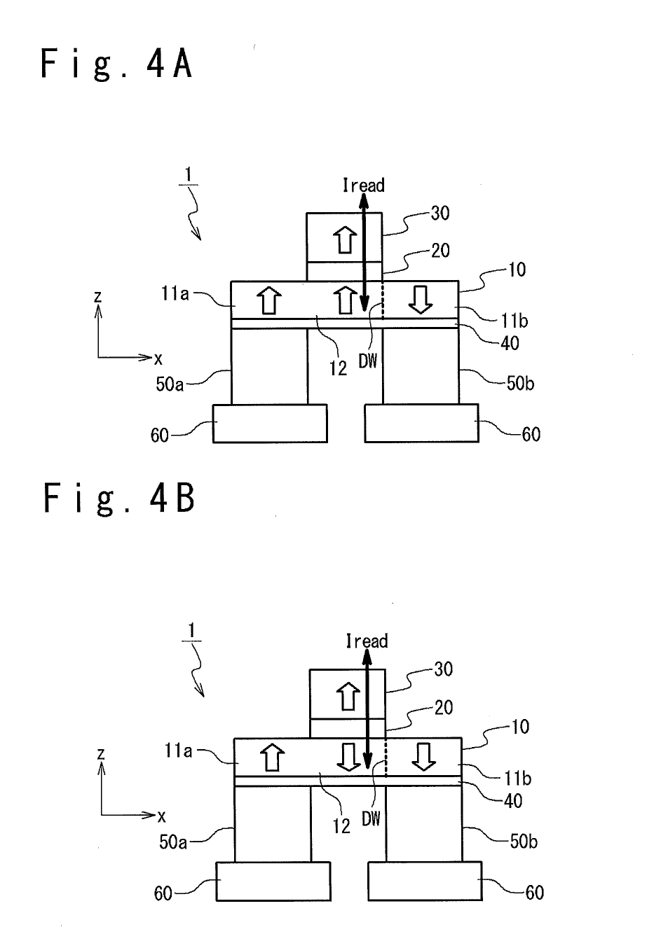

Next, a method of data read from the magnetic memory element 1 will be described with reference to FIGS. 4A and 4B. According to the present exemplary embodiment, the data read is performed by utilizing the tunneling magnetoresistive effect (Tunneling Magnetoresistive effect; TMR effect). For this purpose, a read current Iread is supplied in a direction penetrating through the MTJ (magnetization free layer 10, nonmagnetic layer 20 and pinned layer 30). It should be noted that a direction of the read current Iread is arbitrary.

FIG. 4A shows the read current Iread in the case of the “0” state shown in FIG. 2A. In this case, the MTJ resistance value is relatively small because the magnetization direction of the magnetization free region 12 and the magnetization direction of the pinned layer 30 are parallel to each other. On the other hand, FIG. 4B shows the read current Iread in the case of the “1” state shown in FIG. 2B. In this case, the MTJ resistance value is relatively large because the magnetization direction of the magnetization free region 12 and the magnetization direction of the pinned layer 30 are anti-parallel to each other.

Therefore, a magnitude of the MTJ resistance value can be determined based on a magnitude of the read current Iread or a voltage value depending on the read current Iread. That is, it is possible to detect the magnetization state of the magnetization free layer 10 (data storage layer) and to read the data stored as the magnetization state. In this manner, the nonmagnetic layer 20 and the pinned layer 30 function as the “read structure” for detecting the magnetization state of the magnetization free layer 10 based on the tunneling magnetoresistive effect.

### 1-4. Circuit Configuration

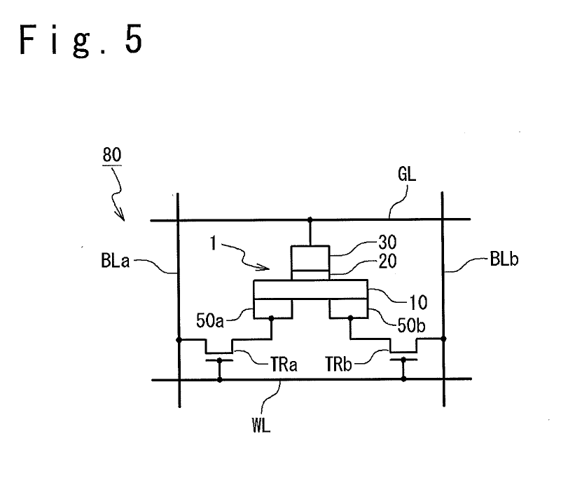

Next, a circuit configuration of the magnetic memory cell having the above-described magnetic memory element 1 will be described. FIG. 5 shows an example of a circuit configuration of one-bit magnetic memory cell. The magnetic memory cell has a 2T-1MTJ (two transistors—one magnetic tunnel junction) configuration including the magnetic memory element 1 and two transistors TRa and TRb. The magnetic memory element 1 is a three-terminal element and is connected to a word line WL, a ground line GL and a bit line pair BLa, BLb. For example, a terminal connected to the pinned layer 30 is connected to the ground line GL. A terminal (electrode layer 60) connected to the first pinning layer 50a is connected to the bit line BLa through the transistor TRa. A terminal (electrode layer 60) connected to the second pinning layer 50b is connected to the bit line BLb through the transistor TRb. Gates of the transistors TRa and TRb are connected to the common word line WL.

At the time of data write, the word line WL is set to the High level and thus the transistors TRa and TRb are turned ON. Moreover, any one of the bit line pair BLa and BLb is set to the High level and the other is set to the Low level (ground level). As a result, the write current Iwrite flows between the bit line BLa and the bit line BLb through the transistors TRa, TRb and the magnetization free layer 10.

At the time of data read, the word line WL is set to the High level and thus the transistors TRa and TRb are turned ON. Moreover, the bit line BLa is set to the Open state and the bit line BLb is set to the High level. As a result, the read current Iread flows from the bit line BLb to the ground line GL penetrating through the MTJ of the magnetic memory element 1.

### 2. Film Configuration and Material of Magnetic Memory Element 1

As described above, the magnetic memory element 1 according to the present exemplary embodiment is provided with the data storage layer (magnetization free layer 10) having the perpendicular magnetic anisotropy. According to the above-mentioned Non Patent Literature 3, the write current required for the current driven domain wall motion can be reduced by using such the data storage layer having the perpendicular magnetic anisotropy.

In order to actually achieve the current driven domain wall motion and to further reduce the write current, it is necessary to appropriately adjust a material of the magnetization free layer 10. More specifically, it is desirable to use a material having small saturation magnetization and large spin polarizability. Furthermore, the perpendicular magnetization must be achieved by using such the material. In other words, it is necessary to achieve crystal orientation such that the perpendicular magnetization can be obtained in the magnetization free layer 10. To this end, the “underlayer 40” on which the magnetization free layer 10 can grow with a preferable crystal orientation is provided.

Preferable film configuration and material for the magnetic memory element 1 according to the present exemplary embodiment will be described hereinafter. In particular, preferable configuration and material with regard to the magnetization free layer 10 and the “underlayer 40” used for forming the magnetization free layer 10 will be described.

### 2-1. Magnetization Free Layer 10

As described above, it is required to achieve the current driven domain wall motion in the magnetization free layer 10. According to Non Patent Literature 4 (A. Thiaville et al., Domain wall motion by spin-polarized current: a micromagnetic study, JOURNAL OF APPLIED PHYSICS, VOL. 95, NO. 11, pp. 7049-7051, 2004.), the current driven domain wall motion is more likely to occur as a parameter gμ_{B}P/2eMₛ becomes larger. Here, the g is Lande g-factor, the μ_{B} is Bohr magneton, the P is spin polarizability, the e is elementary charge, and the Mₛ is saturation magnetization. Since g, μ_{B} and e are physical constants, it is effective for reducing the write current to make the spin polarizability P of the magnetization free layer 10 large and to make the saturation magnetization Ms thereof small.

In terms of the saturation magnetization, an alternately laminated film of transition metal system such as Co/Ni, Co/Pt, Co/Pd, CoFe/Ni, CoFe/Pt, CoFe/Pd and the like is promising as the magnetization free layer 10. It is known that the saturation magnetization of these materials is relatively small. To generalize such a transition metal system laminated film, the magnetization free layer 10 has a laminated structure having a first layer and a second layer that are laminated. The first layer includes any of Fe, Co and Ni or alloy consisting of a plurality of materials selected from Fe, Co and Ni. The second layer includes any of Pt, Pd, Au, Ag, Ni and Cu or alloy consisting of a plurality of materials selected from Pt, Pd, Au, Ag, Ni and Cu.

In particular, Co/Ni among the above-described laminated films has the high spin polarizability. Therefore, it can be said that a Co/Ni laminated film is particularly preferable as the magnetization free layer 10. Actually, it has been experimentally confirmed that the domain wall motion with a high controllability can be achieved by using Co/Ni (refer to Non Patent Literature 5: S. Fukami et al., Low-Current Perpendicular Domain Wall Motion Cell for Scalable High-Speed MRAM, Symposium on VLSI Technology, 12A-2, 2008.).

### 2-2. Underlayer 40

By the way, the magnetic material of the magnetization free layer 10 as mentioned above has an fcc(111) orientation crystal structure that has an fcc structure and whose (111) surface is laminated in the substrate-perpendicular direction. Also, according to Non Patent Literature 6 (G. H. O. Daalderop et al., Prediction and Confirmation of Perpendicular Magnetic Anisotropy in Co/Ni Multilayers, PHYSICAL REVIEW LETTERS, VOL. 68, NO. 5, pp. 682-685, 1992), the perpendicular magnetic anisotropy of the laminated film as mentioned above occurs due to interface magnetic anisotropy at an interface between the films. Therefore, in order to achieve excellent perpendicular magnetic anisotropy in the magnetization free layer 10, it is desirable to provide the “underlayer 40” on which the above-mentioned magnetic material can grow with an excellent fcc(111) orientation.

Non Patent Literature 7 (F. J. A. den Broeder et al., Perpendicular Magnetic Anisotropy and Coercivity of Co/Ni Multilayers, IEEE TRANSACTIONS ON MAGNETICS, VOL. 28, NO. 5, pp. 2760-2765, 1992.) describes that the perpendicular magnetization can be obtained in the Co/Ni laminated film by using a nonmagnetic material underlayer. More specifically, only a thick Au film or a thick Cu film having a thickness of 10 nm or more is used as the underlayer. However, in the case where such a nonmagnetic layer only is used as the underlayer, only weak magnetostatic coupling is obtained between the pinning layer and the data storage layer (magnetization fixed region). If the magnetization fixation of the magnetization fixed region is insufficient, the domain wall DW may get out of the data storage layer due to the data write operation. This causes significant deterioration of operation reliability of the magnetic memory.

In order to normally maintain the domain wall DW in the data storage layer 10, it is necessary to sufficiently fix the magnetization directions of the magnetization fixed regions 11a and 11b in the data storage layer 10. That is, it is important to achieve strong magnetic coupling between the pinning layers 50a, 50b and the magnetization fixed regions 11a, 11b. To that end, a magnetic material is used as the underlayer 40 according to the present exemplary embodiment. That is, the underlayer 40 in FIG. 1A is a “magnetic underlayer” made of a magnetic material. Preferably, a perpendicular magnetic film having the perpendicular magnetic anisotropy is used as the magnetic underlayer 40.

The material of the magnetic underlayer 40 is exemplified by NiFeB. We will describe below that a Co/Ni laminated film being the magnetization free layer 10 can grow with an excellent fcc(111) orientation even when such a NiFeB film is used as the magnetic underlayer 40. That is, we will describe below that excellent perpendicular magnetic anisotropy can be achieved in the magnetization free layer 10 by using a NiFeB film as the magnetic underlayer 40.

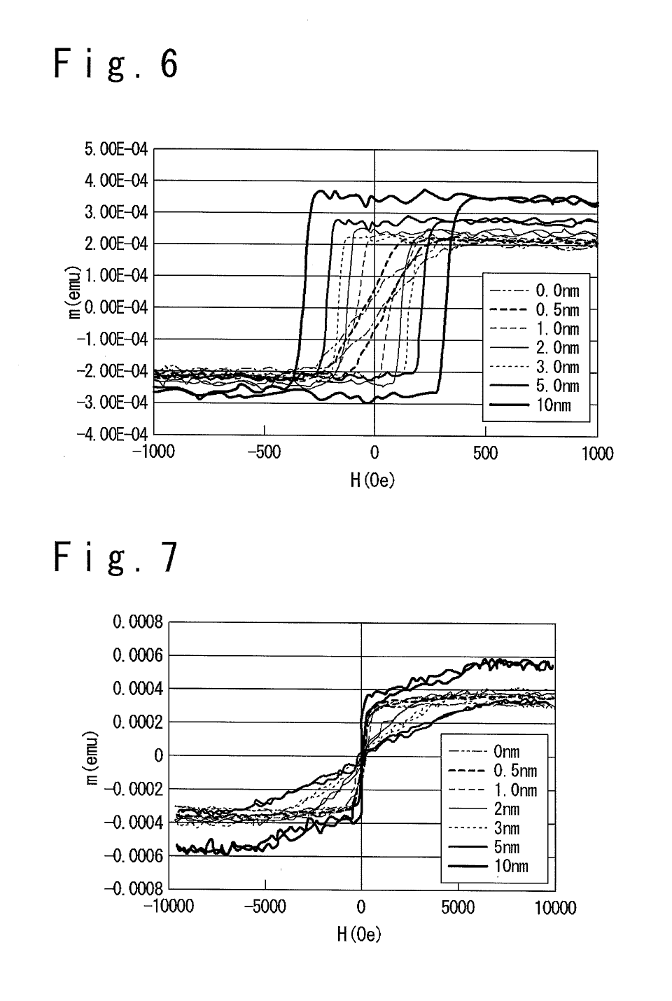

FIGS. 6 and 7 show magnetization curves of the Co/Ni laminated film measured with respect to various NiFeB film thicknesses. FIG. 6 shows the magnetization curves in the substrate-perpendicular direction, and FIG. 7 shows the magnetization curves in the substrate-plane direction. A silicon substrate with an oxide film was used as the substrate. It can be seen from FIGS. 6 and 7 that the Co/Ni laminated film grows with an excellent fcc(111) orientation, namely, an excellent perpendicular magnetization is achieved by appropriately adjusting the NiFeB film thickness.

More specifically, as can be clearly seen from FIG. 6, the Co/Ni laminated film exhibits the perpendicular magnetic anisotropy when the NiFeB film thickness is 2 nm or more. That is, an excellent perpendicular magnetization is achieved when the film thickness is 2 nm or more. This represents that not only the NiFeB film brings the perpendicular magnetic anisotropy to the Co/Ni laminated film but also the NiFeB film itself is perpendicularly magnetized. Moreover, it can be seen from FIG. 7 that a part of the NiFeB film begins to exhibit magnetic anisotropy in the substrate-plane direction when the NiFeB film thickness is increased to about 10 nm. Therefore, the NiFeB film thickness is preferably not more than 10 nm. Thus, it is preferable that the NiFeB film thickness is not less than 2 nm and not more than 10 nm.

The NiFeB film thickness is smaller than a film thickness (not less than 10 nm) of the nonmagnetic material underlayer described in the above-mentioned Non Patent Literature 7. As the underlayer becomes thicker, a resistance value of the underlayer becomes smaller and thus the write current is more likely to flow through the underlayer. In other words, a comparatively large part of the write current flows not in the magnetization free layer 10 but in the underlayer, which causes increase in a total amount of write current including the part that does not contribute to the current driven domain wall motion. This is not preferable in terms of reduction in the write current. In other words, decrease in the thickness of the underlayer is preferable in terms of reduction in the write current.

It should be noted that the material of the magnetic underlayer 40 is not limited to NiFeB. Such materials as NiFeNbB, NiFeZr, NiFeTi, NiFeMoB, NiFeCrB, NiFeNbMoB, NiFeCr, NiFeNb, NiFeMo and NiFeNbMo also can be used as the material of the magnetic underlayer 40. The same effects can be obtained even in a case of a soft magnetic film thus obtained by adding nonmagnetic element to NiFe.

In the above, the case where the material of the magnetization free layer 10 is Co/Ni has been described as an example. The present invention is applicable even when the material of the magnetization free layer 10 is another one (Co/Pd, Co/Pt, CoFe/Pt, CoFe/Pd etc.). Since the resistivity of such the material is roughly equivalent to that of Co/Ni, the above-described underlayer material and film thickness range can be applied similarly and thereby preferable characteristics can be obtained.

### 2-3. Modification Example

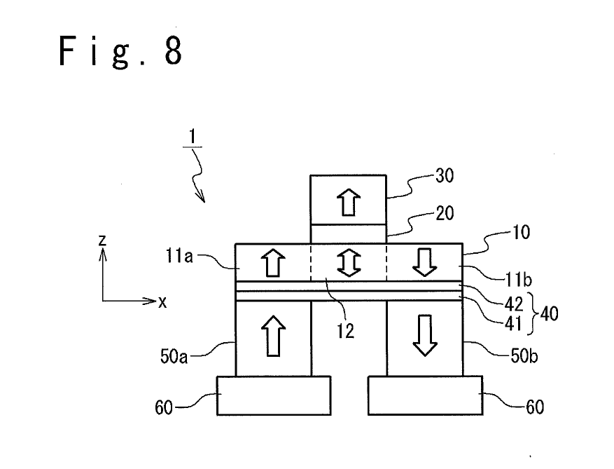

FIG. 8 shows a modification example. In the present modification example, the underlayer 40 has a magnetic underlayer 41 and a nonmagnetic underlayer 42. The magnetic underlayer 41 is similar to the above-described magnetic underlayer 40. On the other hand, the nonmagnetic underlayer 42 is made of a nonmagnetic material. The nonmagnetic underlayer 42 is provided between the magnetization free layer 10 and the magnetic underlayer 41. The nonmagnetic underlayer 42 plays roles of not only further promoting the perpendicular magnetic anisotropy of the magnetization free layer 10 but also magnetically coupling the magnetization free layer 10 and the magnetic underlayer 41.

A material that improves the orientation of the Co-based perpendicular magnetic film and achieves excellent magnetic coupling between magnetic films is preferable as the material of the nonmagnetic underlayer 42. Such the material is exemplified by Au, Pt, Ru, Ir and Pd. Also, a film thickness of the nonmagnetic underlayer 42 is determined such that the magnetic coupling between the magnetization free layer 10 and the magnetic underlayer 41 is maximized and the crystalline orientation of the magnetization free layer 10 is maximized. The optimum film thickness is in a range from 0.2 to 2 nm.

### 3. Effects

According to the present exemplary embodiment, as described above, it is possible to properly achieve the magnetization free layer 10 (data storage layer) having the perpendicular magnetic anisotropy, with regard to the magnetic memory that utilizes the current driven domain wall motion. In particular, sufficiently strong magnetic coupling between the pinning layers 50a, 50b and the magnetization fixed regions 11a, 11b can be achieved. As a result, such a malfunction that the domain wall DW disappears due to the data write operation can be prevented. That is, the operation reliability of the magnetic memory using the current driven domain wall motion is improved.

Moreover, the write current can be reduced sufficiently small in the case where the data storage layer in which the domain wall motion occurs has the perpendicular magnetic anisotropy (refer to Non Patent Literature 3). According to the present exemplary embodiment, the proper magnetization free layer 10 (data storage layer) having the perpendicular magnetic anisotropy is achieved. Therefore, the write current can be reduced.

According to the above-mentioned Non Patent Literature 1, an equivalent cell area to that of an existing embedded SRAM can be achieved by reducing the write current to 0.5 mA or less. In practice, one criterion of the desirable magnitude of the write current is “0.2 mA or less”. The reason is that when the write current is reduced to about 0.2 mA, a minimum layout becomes possible in the 2T-1MTJ cell configuration proposed in the Non Patent Literature 1 and thus substitution for an existing volatile memory and low costs can be achieved. According to the present exemplary embodiment, the write current can be reduced to 0.2 mA or less by appropriately selecting the materials and the film thicknesses of the magnetization free layer 10 and the underlayer 40. The magnetic memory in which the write current is reduced to 0.2 mA or less can be substitution for the existing memory.

While the exemplary embodiments of the present invention have been described above with reference to the attached drawings, the present invention is not limited to these exemplary embodiments and can be modified as appropriate by those skilled in the art without departing from the spirit and scope of the present invention.

While a part of or whole of the above-described exemplary embodiments may be described as the following Supplementary notes, it is not limited to that.

(Supplementary Note 1)

A magnetic memory comprising:

a pinning layer being a perpendicular magnetic film whose magnetization direction is fixed;

an underlayer formed on said pinning layer; and

a data storage layer being a perpendicular magnetic film formed on said underlayer,

wherein said data storage layer comprises:

a magnetization free region whose magnetization direction is reversible; and

a magnetization fixed region magnetically coupled with said pinning layer through said underlayer and whose magnetization direction is fixed by the magnetic coupling, and

wherein said underlayer comprises a magnetic underlayer made of magnetic material.

(Supplementary Note 2)

The magnetic memory according to Supplementary note 1,

wherein said magnetic underlayer includes any of NiFeB, NiFeNbB, NiFeZr, NiFeTi, NiFeMoB, NiFeCrB, NiFeNbMoB, NiFeCr, NiFeNb, NiFeMo and NiFeNbMo.

(Supplementary Note 3)

The magnetic memory according to Supplementary note 1 or 2,

wherein a thickness of said magnetic underlayer is not less than 2 nm and not more than 10 nm.

(Supplementary Note 4)

The magnetic memory according to any one of Supplementary notes 1 to 3,

wherein said data storage layer has a laminated structure of a first layer and a second layer,

wherein said first layer includes any of Fe, Co and Ni or alloy of plural materials selected from a group consisting of Fe, Co and Ni, and

wherein said second layer includes any of Pt, Pd, Au, Ag, Ni and Cu or alloy of plural materials selected from a group consisting of Pt, Pd, Au, Ag, Ni and Cu.

(Supplementary Note 5)

The magnetic memory according to Supplementary note 4,

wherein said first layer includes Co, and

wherein said second layer includes Ni.

(Supplementary Note 6)

The magnetic memory according to any one of Supplementary notes 1 to 5,

wherein said underlayer further comprises a nonmagnetic underlayer made of nonmagnetic material, and

wherein said nonmagnetic underlayer is provided between said data storage layer and said magnetic underlayer.

(Supplementary Note 7)

The magnetic memory according to Supplementary note 6,

wherein said nonmagnetic underlayer includes any of Au, Pt, Ru, Ir and Pd.

This application is based upon and claims the benefit of priority from Japanese patent application No. 2010-066930, filed on Mar. 23, 2010, the disclosure of which is incorporated herein in its entirely by reference.

1. A magnetic memory comprising:
a pinning layer being a perpendicular magnetic film whose magnetization direction is fixed;
an underlayer formed on said pinning layer; and
a data storage layer being a perpendicular magnetic film formed on said underlayer,
wherein said data storage layer comprises:
a magnetization free region whose magnetization direction is reversible; and
a magnetization fixed region magnetically coupled with said pinning layer through said underlayer and whose magnetization direction is fixed by the magnetic coupling, and
wherein said underlayer comprises a magnetic underlayer made of a magnetic material.

2. The magnetic memory according to claim 1,
wherein said magnetic underlayer includes any of NiFeB, NiFeNbB, NiFeZr, NiFeTi, NiFeMoB, NiFeCrB, NiFeNbMoB, NiFeCr, NiFeNb, NiFeMo and NiFeNbMo.

3. The magnetic memory according to claim 1,
wherein a thickness of said magnetic underlayer is not less than 2 nm and not more than 10 nm.

4. The magnetic memory according to claim 1,
wherein said data storage layer has a laminated structure of a first layer and a second layer,
wherein said first layer includes any of Fe, Co and Ni or alloy of plural materials selected from a group consisting of Fe, Co and Ni, and
wherein said second layer includes any of Pt, Pd, Au, Ag, Ni and Cu or alloy of plural materials selected from a group consisting of Pt, Pd, Au, Ag, Ni and Cu.

5. The magnetic memory according to claim 4,
wherein said first layer includes Co, and
wherein said second layer includes Ni.

6. The magnetic memory according to claim 1,
wherein said underlayer further comprises a nonmagnetic underlayer made of a nonmagnetic material, and
wherein said nonmagnetic underlayer is provided between said data storage layer and said magnetic underlayer.

7. The magnetic memory according to claim 6,
wherein said nonmagnetic underlayer includes any of Au, Pt, Ru, Ir and Pd.

8. The magnetic memory according to claim 2,
wherein a thickness of said magnetic underlayer is not less than 2 nm and not more than 10 nm.

9. The magnetic memory according to claim 2,
wherein said data storage layer has a laminated structure of a first layer and a second layer,
wherein said first layer includes any of Fe, Co and Ni or alloy of plural materials selected from a group consisting of Fe, Co and Ni, and
wherein said second layer includes any of Pt, Pd, Au, Ag, Ni and Cu or alloy of plural materials selected from a group consisting of Pt, Pd, Au, Ag, Ni and Cu.

10. The magnetic memory according to claim 3,
wherein said data storage layer has a laminated structure of a first layer and a second layer,
wherein said first layer includes any of Fe, Co and Ni or alloy of plural materials selected from a group consisting of Fe, Co and Ni, and
wherein said second layer includes any of Pt, Pd, Au, Ag, Ni and Cu or alloy of plural materials selected from a group consisting of Pt, Pd, Au, Ag, Ni and Cu.

11. The magnetic memory according to claim 2,
wherein said underlayer further comprises a nonmagnetic underlayer made of a nonmagnetic material, and
wherein said nonmagnetic underlayer is provided between said data storage layer and said magnetic underlayer.

12. The magnetic memory according to claim 3,
wherein said underlayer further comprises a nonmagnetic underlayer made of a nonmagnetic material, and
wherein said nonmagnetic underlayer is provided between said data storage layer and said magnetic underlayer.

13. The magnetic memory according to claim 4,
wherein said underlayer further comprises a nonmagnetic underlayer made of a nonmagnetic material, and
wherein said nonmagnetic underlayer is provided between said data storage layer and said magnetic underlayer.

14. The magnetic memory according to claim 5,
wherein said underlayer further comprises a nonmagnetic underlayer made of a nonmagnetic material, and
wherein said nonmagnetic underlayer is provided between said data storage layer and said magnetic underlayer.
